(19) United States
(12) Patent Application Publication
(10) Pub. No.: US 2008/0290405 A1
(43) Pub. Date: Nov. 27, 2008

(54) Power mosfet diode

(76) Inventor: Chao-Cheng Lu, Taipei (TW)

Correspondence Address: Chao-Cheng Lu;4-4, Alley 27, Lane 143, Chun Kung Road, Taipei, TW

(21) Appl. No.: 11/804,390

(22) Filed: May 21, 2007

(51) Int. Cl. H01L 29/78

(52) U.S. Cl. 257/330; 257/E29.257

(57) ABSTRACT

A power MOSFET diode includes a plurality of unit elements, each of which has a gate and a drain that are connected to each other by the structure and the process of UMOS, VMOS, VDMOS, and etc., so as to integrate the unit elements into a PMD without any body diode of the traditional UMOS, VMOS, or VDMOS for providing a one-way electrical conductivity. The PMD is different from traditional diodes or Schottky diodes, because a forward bias is existed when the traditional diodes or Schottky diodes conduct the electricity on one-way. However, a drain-source on-state resistance (RDS) is used to replace the consumption of the forward bias when the PMD conducts the electricity on one-way. Due to the RDS of the PMD is lower and easy to be parallel connected to each other, the PMD can be used to substantially lower the power consumption and applied to various industries.

### FIELD OF THE INVENTION

The present invention relates to a power metal oxide semiconductor field effect transistor (power MOSFET), and more particularly to a power MOSFET diode (PMD) without any traditional body diode while also connecting a gate and a drain to each other, so as to solve the problem of a traditional diode or Schottky diode in which there is a substantial voltage drop consumption of a forward bias during rectifying, wherein in a practical application, an operation voltage of a traditional memory of a computer drops while the consumption of an electric current of the memory increases, such as a direct current power supply 1V, 100 A provided with the traditional diode or Schottky Diode, is not enough to stably rectify; the PMD according to the present invention calculates a consumption based on a drain resistor during rectifying, so as to substantially enhance a rectifying efficiency thereof, while the PMD is easy to be selectively applied to a parallel connection mode, a series connection mode, or a parallel-series connection mode, i.e. the PMD of the present invention has a higher connection flexibility in comparison with the traditional diode or Schottky diode; all of structures and processes which will be mentioned hereinafter, such as U-groove power MOSFET (UMOS), V-groove power MOSFET (VMOS), or vertical double diffused power MOSFET (VDMOS), are possible embodiments of the present invention; and the present invention includes a process technology of power JFET and other process, only if carrying out the purpose and function of the present invention.

### BACKGROUND OF THE INVENTION

Traditionally, a switching power supply is provided with some diodes, Schottky diodes, or power MOSFETs for synchronous rectifying, wherein the power MOSFETs has a complex and expensive circuit of synchronous rectification which must work with a synchronous rectification integrated circuit. However, a power MOSFET diode (PMD) of the present invention has an outline similar to a traditional diode, and is characterized in that the PMD is provided with two terminals, so as to be used to directly replace the traditional diode or Schottky diode for the purpose of enhancing a rectifying efficiency.

### SUMMARY OF THE INVENTION

A primary object of the present invention is to provide a power MOSFET diode, which is used to solve the problem of the traditional rectifying function with the higher voltage drop consumption existed in the traditional diode or Schottky diode, so as to enhance the rectifying efficiency of a semiconductor element during rectifying. A secondary object of the present invention is to provide a power MOSFET diode, which is used to simplify the complex structure of the traditional synchronous rectification circuit included with power MOSFETs.

To solve the problem of the traditional rectifying function with higher voltage drop consumption as mentioned above, a preferred embodiment of the present invention provides the following features:

1. In a manufacturing process of enhancement mode power MOSFETs, the enhancement mode power MOSFETs exclude any body diode, and are respectively provided with a gate and a drain connected to each other, so as to form a power metal oxide semiconductor field effect transistor diode (Power MOSFET Diode, PMD).

2. The PMD of the present invention can be optionally used to replace the traditional diode or Schottky diode without changing the other original circuit, so as to enhance the rectifying efficiency.

It is therefore tried by the inventor to develop a power MOSFET diode to solve the problems existing in the traditional technology, such as the problem of the synchronously rectification of the traditional diode, Schottky diode, and power MOSFET, as described above.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1A is a cross-sectional view of a N channel structure according to a preferred embodiment of the present invention;

FIG. 1B is a cross-sectional view of a P channel structure according to another preferred embodiment of the present invention;

FIG. 2A is a cross-sectional view of the N channel structure according to the preferred embodiment of the present invention in operation, similar to FIG. 1A;

FIG. 2B is another cross-sectional view of the N channel structure according to the preferred embodiment of the present invention in operation, similar to FIG. 2A;

FIG. 3A is a cross-sectional view of the P channel structure according to the preferred embodiment of the present invention in operation, similar to FIG. 1B;

FIG. 3B is another cross-sectional view of the P channel structure according to the preferred embodiment of the present invention in operation, similar to FIG. 3A;

FIG. 4 is a cross-sectional view of a unit element of a power MOSFET diode according to a preferred embodiment of the present invention; and

FIG. 5 is a cross-sectional view of the power MOSFET diode according to the preferred embodiment of the present invention.

### DETAILED DESCRIPTION OF THE PREFERRED EMBODIMENTS

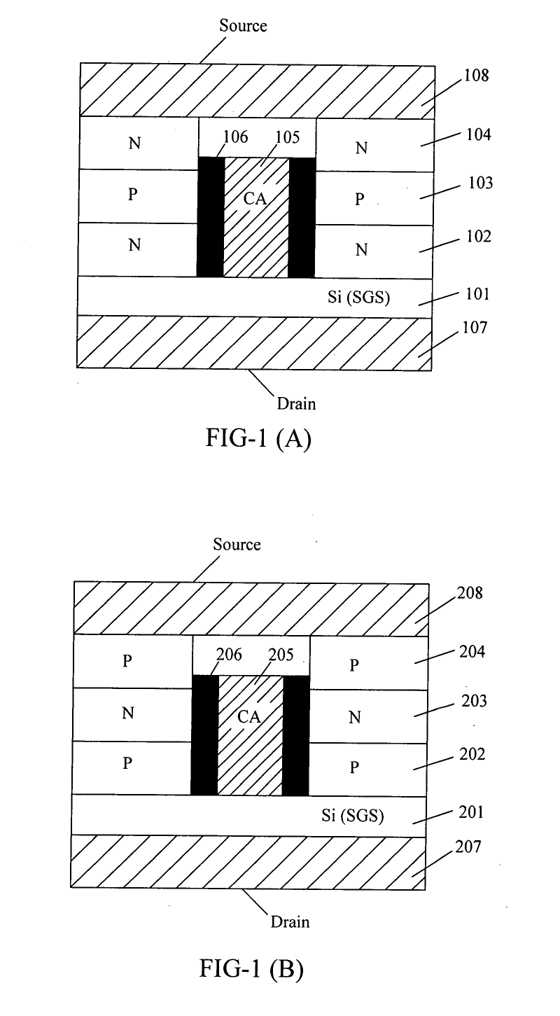

Referring now to FIG. 1A, a N channel structure according to a preferred embodiment of the present invention is illustrated. As shown, the N channel structure comprises a N type source 104, a P type base 103, a N type drain 102, an oxide semiconductor (OS) 106, a metal gate 105, a silicon substrate 101, and a pair of contact alloys (CA) 107, 108; wherein the metal gate 105, the silicon substrate 101 and the contact alloy 107 are integrated into a T-shaped groove formed conductor, so as to be defined as a drain. Meanwhile, the N type source 104 and the contact alloy 108 are integrated into another conductor, so as to be defined as a source. The oxide semiconductor 106 is used as an insulator for surrounding the metal gate 105, i.e. a space between a portion of the N type source 104, the P type base 103, the N type drain 102, and the metal gate 105 or a space between the P type base 103, the N type drain 102, and the metal gate 105 is filled with the insulator, so as to form a metal oxide semiconductor (MOS) capacitor.

Referring now to FIG. 1B, a P channel structure according to another preferred embodiment of the present invention is illustrated. As shown, the P channel structure comprises a P type source 204, a N type base 203, a P type drain 202, an oxide semiconductor (OS) 206, a metal gate 205, a silicon substrate 201, and a pair of contact alloys (CA) 207, 208, wherein the metal gate 205, the silicon substrate 201 and the contact alloy 207 are integrated into a T-shaped groove formed conductor, so as to be defined as a drain. Meanwhile, the P type source 204 and the contact alloy 208 are integrated into a conductor, so as to be defined as a source. The oxide semiconductor 206 is used as an insulator for surrounding the metal gate 205, i.e. a space between a portion of the P type source 204, the N type base 203, the P type drain 202, and the metal gate 205 or a space between the N type base 203, the P type drain 202, and the metal gate 205 is filled with the insulator, so as to form a metal oxide semiconductor (MOS) capacitor.

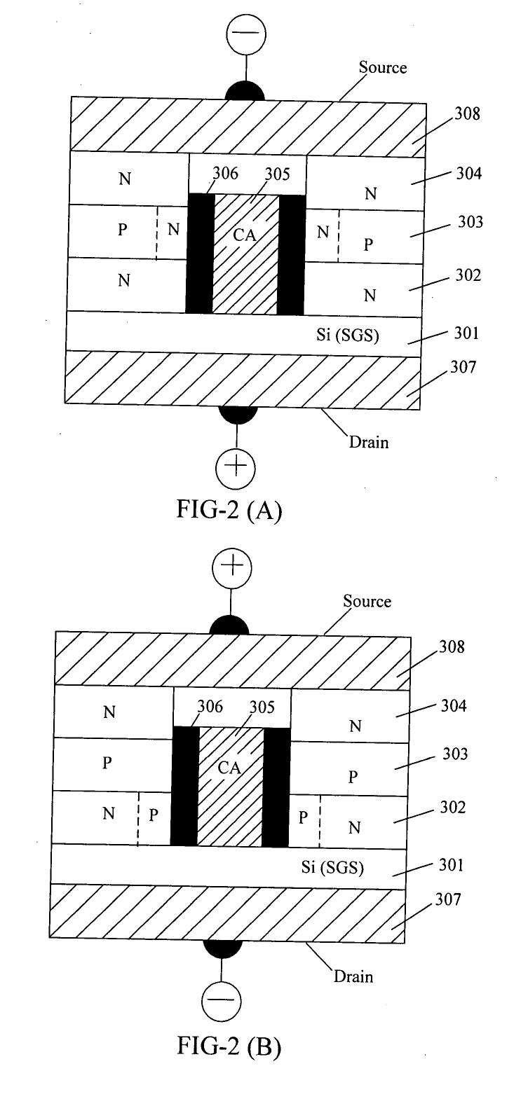

Referring now to FIG. 2A, a N channel structure according to the preferred embodiment of the present invention in operation is illustrated and similar to FIG. 1A. As shown, the N channel structure comprises a N type source 304, a P type base 303, a N type drain 302, an oxide semiconductor (OS) 306, a metal gate 305, a silicon substrate 301, and a pair of contact alloys (CA) 307, 308. The drain of the N channel structure is electrically connected to a first external power source V⁺, while the source thereof is electrically connected to a second external power source V⁻. If the metal gate 305 is electrically connected to a third external power with a greater positive voltage, the MOS capacitor will generate a stronger electric field between the drain and the source of the MOS capacitor corresponding to the greater positive voltage of the third external power, so as to generate positive charges in the metal gate 305. Meanwhile, the N type source 304, the P type base 303, and the N type drain 302 are respectively provided with a semiconductor surface facing an insulator of the oxide semiconductor 306, wherein the semiconductor surfaces of the N type source 304, the P type base 303, and the N type drain 302 are accumulated with negative charges. According to a theory that the Intrinsic Fermi energy level is lower than the Fermi energy level, and the conduction band is relatively closer to the Fermi energy level than the valence band, said semiconductor surfaces of the present invention adjacent to the insulator has a N type semiconductor property. If the positive voltage of the metal gate 305 is increased up to a predetermined value, some of the semiconductor property of said semiconductor surfaces will be converted from P type to N type, so as to form an inversion layer of electrons of a MOS interface, i.e. the MOS capacitor semiconductor surface of the P type base 303 facing the insulator has a temporary semiconductor property of N type. Thus, a temporary N type region formed on the MOS capacitor semiconductor surface is defined as a N channel for being an electrical path between the drain and the source. On the other hand, referring now to FIG. 2B, the source of the N channel structure is electrically connected to a first external power source V⁺, while the drain thereof is electrically connected to a second external power source V⁻. The MOS capacitor semiconductor surface of the N type drain 302 facing the insulator will have a temporary semiconductor property of P type, while the P type base 303 still has a semiconductor property of P type and the N type source 304 still has a semiconductor property of N type. Thus, in two charged regions of N-P junction, there are no electrons and holes existed in a space charge region (i.e. a depletion region) of the N-P junction under an internal electric field, while a region between the source and the drain is in an insulation status. Referring back to FIGS. 2A and 2B, when the drain is electrically connected to a positive power source and the source is electrically connected to a negative power source, a N channel is generated to be an electrical path. When the drain is electrically connected to a negative power source and the source is electrically connected to a positive power source, a depletion region is generated to be an open circuit between the drain and the source. Therefore, the MOS capacitor of the present invention is used as a switch that only has a one-way electrical conductivity.

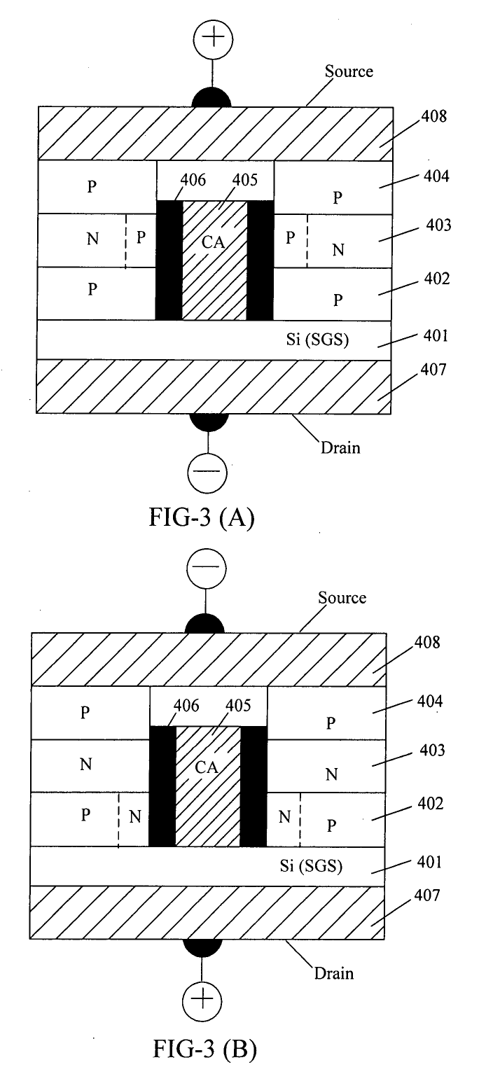

Referring now to FIG. 3A, a P channel structure according to the preferred embodiment of the present invention in operation is illustrated and similar to FIG. 1B. As shown, the P channel structure comprises a P type source 404, a N type base 403, a P type drain 402, an oxide semiconductor (OS) 406, a metal gate 405, a silicon substrate 401, and a pair of contact alloys (CA) 407, 408. The source of the P channel structure is electrically connected to a first external power source V⁺, while the drain thereof is electrically connected to a second external power source V⁻. If the metal gate 405 is electrically connected to a third external power with a greater negative voltage, the MOS capacitor will generate a stronger electric field between the drain and the source of the MOS capacitor corresponding to the greater negative voltage of the third external power, so as to generate negative charges in the metal gate 405. Meanwhile, the P type source 404, the N type base 403, and the P type drain 402 are respectively provided with a semiconductor surface facing an insulator of the oxide semiconductor 406, wherein the semiconductor surfaces of the P type source 404, the N type base 403, and the P type drain 402 are accumulated with positive charges. According to the same theory that the Intrinsic Fermi energy level is lower than the Fermi energy level and the conduction band is relatively closer to the Fermi energy level than the valence band, said semiconductor surfaces of the present invention adjacent to the insulator has a P type semiconductor property. If the negative voltage of the metal gate 405 is increased up to a predetermined value, some of the semiconductor property of said semiconductor surfaces will be converted from N type to P type, so as to form an inversion layer of holes of a MOS interface, i.e. the MOS capacitor semiconductor surface of the N type base 403 facing the insulator has a temporary semiconductor property of P type. Thus, a temporary P type region formed on the MOS capacitor semiconductor surface is defined as a P channel for being an electrical path between the drain and the source. On the other hand, referring now to FIG. 3B, the drain of the P channel structure is electrically connected to a first external power source V⁺, while the source thereof is electrically connected to a second external power source V⁻. The MOS capacitor semiconductor surface of the P type drain 402 facing the insulator will have a temporary semiconductor property of N type, while the N type base 403 still has a semiconductor property of N type and the P type source 404 still has a semiconductor property of P type. Thus, in two charged regions of N-P junction, there are no electrons and holes existed in a space charge region (i.e. a depletion region) of the N-P junction under an internal electric field, while a region between the source and the drain is in an insulation status. Referring back to FIGS. 3A and 3B, when the source is electrically connected to a positive power source and the drain is electrically connected to a negative power source, a P channel is generated to be an electrical path. When the source is electrically connected to a negative power source and the drain is electrically connected to a positive power source, a depletion region is generated to be an open circuit between the drain and the source. Therefore, the MOS capacitor of the present invention is used as a switch that only has a one-way electrical conductivity.

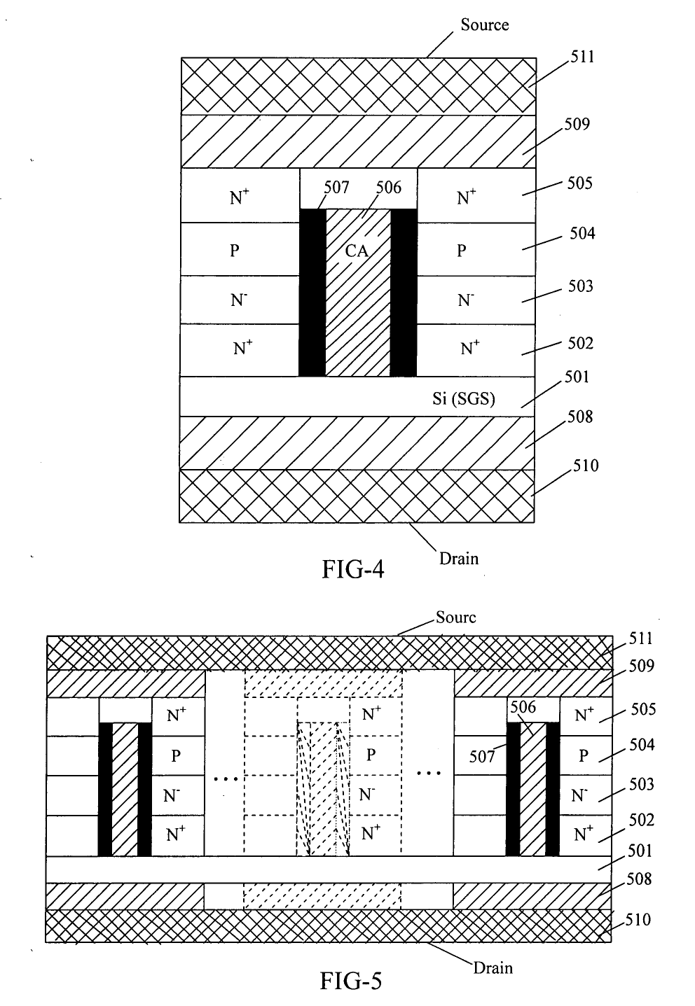

Referring now to FIG. 4, a unit element of a power MOSFET diode (PMD) according to a preferred embodiment of the present invention is illustrated. As shown, the unit element can be selected from a U-groove power MOSFET (UMOS) due to a smaller drain-source on-state resistance (RDS) of UMOS, but the unit element also can be selected from a V-groove power MOSFET (VMOS) or a vertical double diffused power MOSFET (VDMOS) according to the difficulty of relevant manufacturing process, the manufacture cost, and the need of the unit element, i.e. the unit element also can be selected from various trench-form power MOSFETs without limiting to said UMOS, VMOS, and VDMOS, only if a process technology based on a concept of an enhancement mode power MOSFET can be used to carry out the function and the object of the power MOSFET diode of the present invention. As shown, the power MOSFET diode of the present invention comprises a silicon substrate 501 made of semiconductor grade silicon (SGS), an epitaxial layer (i.e. epilayer) of an N⁺ type drain 502 diffused from the silicon substrate 501, a N⁻ type drift region 503 extended outward from the N⁺ type drain 502, a P type base 504 selectively formed in the high-resistance N⁻ type drift region 503 by diffusion or ion implantation, and a N⁺ type source 505 selectively formed in the P type base 504 by diffusion or ion implantation. The N⁺ type drain 502, the N⁻ type drift region 503, the P type base 504, and the N⁺ type source 505 can be selectively formed by various technologies of diffusion or ion implantation, only if any technology and process can be used to carry out the structure of the present invention. Furthermore, a gate region of the present invention can be formed by an etch technology and a treatment of SiO₂, wherein a metal gate 506 is a conductor made of a metal alloy or a contact alloy (508, 509) by a metallization process. The metal gate 506, the N⁺ type drain 502, and the silicon substrate 501 are electrically connected to each other with a high electrical conductivity, but are insulated from the P type base 504 and the N⁺ type source 505. Moreover, an oxide semiconductor (OS) 507 is used as an insulator for surrounding the metal gate 506. According to a semiconductor theory that a breakdown voltage of a N-P junction is related to the doping concentration and the depth of the N⁺ type drain 502 and the N⁻ type drift region 503, and thus the N⁺ type drain 502 and the N⁻ type drift region 503 of the present invention can be used to increase the breakdown voltage. In the preferred embodiment of the present invention, the doping concentration and the depth of the N⁺ type drain 502 and the N⁻ type drift region 503 can be suitably varied according to a predetermined value of the breakdown voltage without limitation. Furthermore, the P type base 504 can be selected from a P⁺ type base or a P⁻ type base. Briefly, the N⁺ type drain 502, the N⁻ type drift region 503, the P type base 504 (P⁺ or P⁻ type), or the N⁺ type source 505 can be suitably varied according to an actual need of the PMD of the present invention without limitation. After forming the structure of the N⁺ type drain 502, the N⁻ type drift region 503, the P type base 504, and the N⁺ type source 505, a pair of contact alloys 508, 509 are formed outside of the silicon substrate 501 (and the N⁺ type source 505), respectively, and a pair of conductors 510, 511 are formed outside the contact alloys 508, 509, so as to finish a unit element of PMD of the present invention.

Referring now to FIG. 5, a power MOSFET diode (PMD) according to a preferred embodiment of the present invention is illustrated. As shown, the PMD comprises a plurality of the unit elements in FIG. 4 which are parallel-connected to each other. Firstly, the plurality of the unit elements are manufactured according to the RDS value, the drain source breakdown voltage value, the drain current value, the business specification, and the specific specification. Then, the count of the unit elements are decided, while the connection mode of the unit elements are decided, such as a parallel connection mode, a series connection mode, or a parallel-series connection mode. As shown in FIG. 5, the plurality of the unit elements are parallel connected to each other, wherein the conductor 510 of the drain of one of the unit elements is parallel connected to the conductor 510 of the drain of the other unit elements, so as to integrate into a common terminal of the drain of the whole PMD. Meanwhile, the conductor 511 of the source of one of the unit elements is parallel connected to the conductor 511 of the source of the other of the unit elements, so as to integrate into a common terminal of the source of the whole PMD. Thus, the PMD of the present invention is characterized in that the PMD is provided with two terminals and can be finished as an industrial product by assembling, packaging, and inspecting.

As described above, the PMD of the present invention is used to remove the body diode of the traditional enhancement mode power MOSFETs by the lower drain-source on-state resistance (RDS) of the power MOSFET of the present invention, so as to lower the voltage drop and the power consumption, as well as enhancing the rectifying efficiency. Therefore, the PMD of the present invention can be applied to various electronic devices, such as personal computers, notebook computers, televisions, refrigerators, air conditioners, and other household appliances or industrial appliances, which must convert low-frequency or high-frequency electric power into a direct current (D.C.) power, in order to enhance the rectifying efficiency thereof and make the D.C. electronic devices more compact.

The present invention has been described with a preferred embodiment thereof and it is understood that many changes and modifications to the described embodiment can be carried out without departing from the scope and the spirit of the invention that is intended to be limited only by the appended claims.

What is claimed is:

1. A power MOSFET diode, comprising:
a first terminal electrically connected to the drain and metal gate of an enhancement mode power MOSFET during manufacture process;
a second terminal electrically connected to the source of said enhancement mode power MOSFET;
such that said power MOSFET diode providing a rectification function.

2. A power MOSFET diode, comprising a plurality of unit elements, each of the unit elements comprising:
a N type source having a first side connected to a P type base, a second side connected to a first contact alloy, and a third side partially connected to an oxide semiconductor;
a P type base having a first side connected to the N type source, a second side connected to a N type drain, and a third side connected to the oxide semiconductor;
a N type drain having a first side connected to the P type base, a second side connected to a silicon substrate, and a third side connected to the oxide semiconductor;
a silicon substrate having a first side connected to a second contact alloy for being a drain, and a second side connected to the N type drain and the oxide semiconductor;
a oxide semiconductor respectively connected to the N type source, the P type base, the N type drain, the silicon substrate, the first contact alloy, and the second contact alloy;
a metal gate surrounded by the oxide semiconductor and having a side connected to the silicon substrate;
a first contact alloy connected to the N type source for being a source; and
a second contact alloy connected to the silicon substrate for being the drain;
the unit element characterized in that: the metal gate, the N type drain, the silicon substrate, and the second contact alloy are integrated into a conductor for being the drain, while the N type source and the first contact alloy are integrated into another conductor for being the source, so as to form two terminals of the unit element.

3. The power MOSFET diode of claim 2, wherein the unit elements are connected to each other in a parallel connection mode, a series connection mode, a series-parallel connection mode, or a parallel-series connection mode.

4. The power MOSFET diode of claim 2, wherein the shape of the metal gate, the silicon substrate, and the second contact alloy is selected from a T-groove, a U-groove, a V-groove, or a vertical double diffused groove with respect to the drain.

5. The power MOSFET diode of claim 2, wherein when the metal gate is electrically connected to a positive power source, the unit element is formed with a N channel for being an electrical path between the drain and the source, and wherein the oxide semiconductor is used as an insulator for surrounding the metal gate, and a side of the oxide semiconductor is connected to the P type base and the N type drain, so as to form a metal oxide semiconductor (MOS) capacitor.

6. The power MOSFET diode of claim 2, wherein the doping concentration and the depth of semiconductor of the unit elements are varied in relation to a predetermined value of a breakdown voltage of the unit elements, and wherein the N type drain is selected from a N⁺/N type drain or a N⁺/N⁻ type drain; the P type base is selected from a P⁺ type base or a P⁻ type base; and the N type source is selected from a N⁺ type source or a N⁻ type source.

7. A power MOSFET diode, comprising a plurality of unit elements, each of the unit elements comprising:
a P type source having a first side connected to a N type base, a second side connected to a first contact alloy, and a third side partially connected to an oxide semiconductor;
a N type base having a first side connected to the P type source, a second side connected to a P type drain, and a third side connected to the oxide semiconductor;
a P type drain having a first side connected to the N type base, a second side connected to a silicon substrate, and a third side connected to the oxide semiconductor;
a silicon substrate having a first side connected to a second contact alloy for being a drain, and a second side connected to the P type drain and the oxide semiconductor;
a oxide semiconductor respectively connected to the P type source, the N type base, the P type drain, the silicon substrate, the first contact alloy, and the second contact alloy;
a metal gate surrounded by the oxide semiconductor and having a side connected to the silicon substrate;
a first contact alloy connected to the P type source for being a source; and
a second contact alloy connected to the silicon substrate for being the drain;
the unit element characterized in that: the metal gate, the P type drain, the silicon substrate, and the second contact alloy are integrated into a conductor for being the drain, while the P type source and the first contact alloy are integrated into another conductor for being the source, so as to form two terminals of the unit element.

8. The power MOSFET diode of claim 7, wherein the unit elements are connected to each other in a parallel connection mode, a series connection mode, a series-parallel connection mode, or a parallel-series connection mode.

9. The power MOSFET diode of claim 7, wherein when the metal gate is electrically connected to a negative power source, the unit element is formed with a P channel for being an electrical path between the drain and the source, and wherein the oxide semiconductor is used as an insulator for surrounding the metal gate, and a side of the oxide semiconductor is connected to the N type base and the P type drain, so as to form a metal oxide semiconductor (MOS) capacitor.

10. The power MOSFET diode of claim 7, wherein the shape of the metal gate, the silicon substrate, and the second contact alloy is selected from a T-groove, a U-groove, a V-groove, or a vertical double diffused groove with respect to the drain.

11. The power MOSFET diode of claim 7, wherein the doping concentration and the depth of semiconductor of the unit elements are varied in relation to a predetermined value of a breakdown voltage of the unit elements, and wherein the P type drain is selected from a P⁺/P type drain or a P⁺/P⁻ type drain; the N type base is selected from a N⁺ type base or a N⁻ type base; and the P type source is selected from a P⁺ type source or a P⁻ type source.
